(19) United States
(12) Patent Application Publication
(10) Pub. No.: US 2023/0106035 A1
(43) Pub. Date: Apr. 6, 2023

(54) ANISOTROPIC CONDUCTIVE SHEET, ELECTRICAL INSPECTION DEVICE, AND ELECTRICAL INSPECTION METHOD

(71) Applicant: Mitsui Chemicals, Inc., Tokyo (JP)

(72) Inventors: Katsunori NISHIURA, Chiba-shi, Chiba (JP); Daisuke YAMADA, Hidaka-shi, Saitama (JP); Yojiro YAMAMOTO, Osaka (JP)

(21) Appl. No.: 17/759,516

(22) PCT Filed: Jan. 26, 2021
(86) PCT No.: PCT/JP2021/002673

§ 371 Date: Jul. 27, 2022

(30) Foreign Application Priority Data
Jan. 31, 2020 (JP) 2020-015630

(51) Int. Cl. G01R 31/28; H01B 5/16; H01B 1/02; C23C 18/16; C23C 18/31; C25D 5/56; C25D 7/04; C23C 28/00

(52) U.S. Cl. CPC G01R 31/2801; C23C 18/31; C23C 18/1653; C23C 28/00; C25D 5/56; C25D 7/04; H01B 1/02; H01B 5/16

(57) ABSTRACT

An anisotropic conductive sheet has an insulation layer having a plurality of through-holes and a plurality of conductive layers each arranged on an inner wall surface of each of the plurality of through-holes. Each of the conductive layers has a base layer arranged on the inner wall surface of each of the through-holes and a metal plating layer arranged so as to contact with metal nanoparticles or a metal thin film in the base layer or the metal thin film. The base layer includes metal nanoparticles or a metal thin film and a binder, wherein at least a portion of the binder is arranged between the inner wall of each of the through-holes and the metal nanoparticles or the metal thin film. The binder is a sulfur-containing compound having a thiol group, a sulfide group or a disulfide group.

### TECHNICAL FIELD

The present invention relates to an anisotropic conductive sheet, an electrical testing apparatus, and an electrical testing method.

### BACKGROUND ART

Semiconductor devices such as printed circuit boards mounted in electronic products are usually subjected to electrical testing. Usually, electrical testing is performed by electrically contacting a substrate (with electrodes) of an electrical testing apparatus with terminals of an object to be inspected (herein also referred to as “inspection object”) such as a semiconductor device, and reading the current obtained when a predetermined voltage is applied between the terminals of the inspection object. Then, for the purpose of reliably performing the electrical contact between the electrodes of the substrate of the electrical testing apparatus and the terminals of the inspection object, an anisotropic conductive sheet is disposed between the substrate of the electrical testing apparatus and the inspection object.

An anisotropic conductive sheet has conductivity in the thickness direction and insulating properties in the surface direction, and is used as a probe (contact) in electrical testing. In particular, for the purpose of reliably performing the electrical connection between the substrate of the electrical testing apparatus and the inspection object, an anisotropic conductive sheet that elastically deforms in the thickness direction is desired.

Known as an anisotropic conductive sheet that elastically deforms in the thickness direction is, for example, an anisotropic conductive sheet including a sheet and a plurality of conductive parts (see, for example, Patent Literatures (hereinafter, referred to as PTLs) 1 and 2. In the anisotropic conductive sheet, the sheet includes a plurality of through holes penetrating through the sheet in the thickness direction, and the plurality of conductive parts are disposed on the inner wall surfaces of the through holes.

Such an anisotropic conductive sheet may be obtained by forming a plurality of through holes through the base sheet and then forming conductive parts on the inner wall surfaces of the through holes by plating (e.g., electroless plating and electrolytic plating).

### CITATION LIST

### Patent Literature

PTL 1 Japanese Patent Application Laid-Open No. 2007-220512

PTL 2 Japanese Patent Application Laid-Open No. 2010-153263

### SUMMARY OF INVENTION

### Technical Problem

Electroless Ni plating is known as a typical example of electroless plating. However, an anisotropic conductive sheet obtained by performing electroless Ni plating on the inner wall surfaces of the through holes and then performing electrolytic plating to form conductive parts (conductive layers) has, for example, the following disadvantage: the layer formed by the electrolytic plating is more likely to be peeled off while the anisotropic conductive sheet is repeatedly and elastically deformed by pressurization and depressurization during electrical testing. The reason therefor can be considered as follows. The electroless Ni plating layer is hard and cannot follow the elastic deformation of the sheet caused by the pressurization and depressurization, and thus the electroless Ni plating layer is peeled off.

In view of the above disadvantage, an object of the present invention is to provide an anisotropic conductive sheet capable of minimizing the peeling of a conductive layer associated with elastic deformation of the sheet in the thickness direction, and capable of performing satisfactory electrical connection between the substrate of the electrical testing apparatus and an inspection object; and an electrical testing apparatus and an electrical testing method each using the anisotropic conductive sheet.

### Solution to Problem

The above-described object can be achieved by the following configurations.

An anisotropic conductive sheet of the present invention includes:

an insulating layer including a first surface located on one side in a thickness direction, a second surface located on another side in the thickness direction, and a plurality of through holes each extending between the first surface and the second surface; and a plurality of conductive layers disposed on corresponding inner wall surfaces of the plurality of through holes, in which each of the plurality of conductive layers includes: a base layer that is disposed on the corresponding inner wall surface of the through hole, the base layer containing a metal-containing thin film and a binder with at least a part thereof disposed between the inner wall surface of the through hole and the metal-containing thin film, and a metal plating layer disposed on or above the base layer so as to be in contact with the metal-containing thin film, and in which the binder is a sulfur-containing compound having a thiol group, a sulfide group, or a disulfide group.

An electrical testing apparatus of the present invention includes: an inspection substrate including a plurality of electrodes; and the anisotropic conductive sheet of the present invention disposed on or above the surface, where the plurality of electrodes are disposed, of the inspection substrate.

An electrical testing method according to the present invention includes: stacking an inspection substrate including a plurality of electrodes and an inspection object including a terminal via the anisotropic conductive sheet of the present invention, and electrically connecting the plurality of electrodes of the inspection substrate with the terminal of the inspection object via the anisotropic conductive sheet.

### Advantageous Effects of Invention

The present invention can provide an anisotropic conductive sheet capable of minimizing the peeling of a conductive layer associated with elastic deformation of the sheet in the thickness direction, and capable of performing satisfactory electrical connection between the substrate of the electrical testing apparatus and an inspection object; and an electrical testing apparatus and an electrical testing method each using the anisotropic conductive sheet.

### BRIEF DESCRIPTION OF DRAWINGS

FIG. 1A is a plan view illustrating an anisotropic conductive sheet according to an embodiment (present embodiment), and FIG. 1B is a partially enlarged sectional view of the anisotropic conductive sheet of FIG. 1A taken along line 1B-1B;

FIG. 2 is an enlarged view of FIG. 1B;

FIG. 3 is an enlarged schematic view of region A in FIG. 2;

FIGS. 4A to 4F are schematic cross-sectional views illustrating a method for producing the anisotropic conductive sheet according to the present embodiment;

FIG. 5 is a sectional view illustrating an electrical testing apparatus according to the present embodiment;

FIGS. 6A and 6B are partially enlarged views illustrating an anisotropic conductive sheet according to other embodiments; and

FIG. 7A is a plan view illustrating the anisotropic conductive sheet according to yet another embodiment, and FIG. 7B is a partially enlarged sectional view of the anisotropic conductive sheet of FIG. 7A taken along line 7B-7B.

### DESCRIPTION OF EMBODIMENTS

### 1. Anisotropic Conductive Sheet

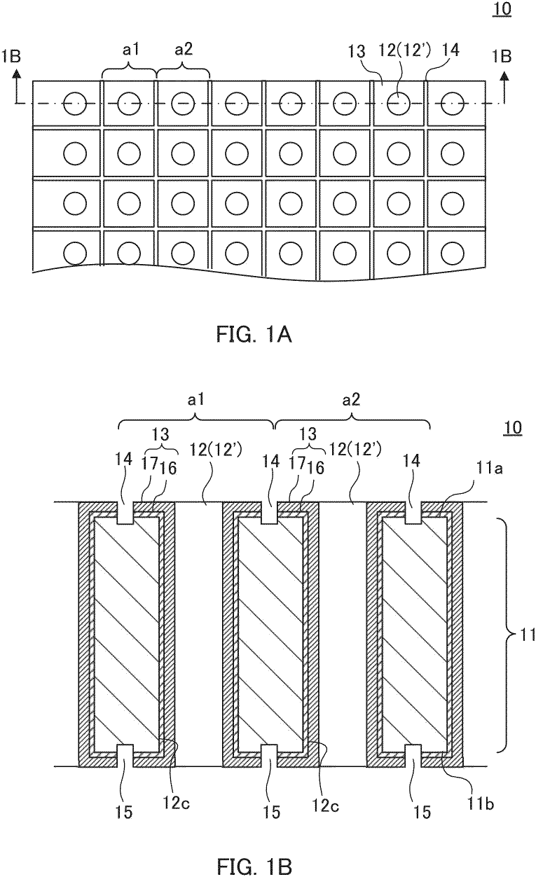

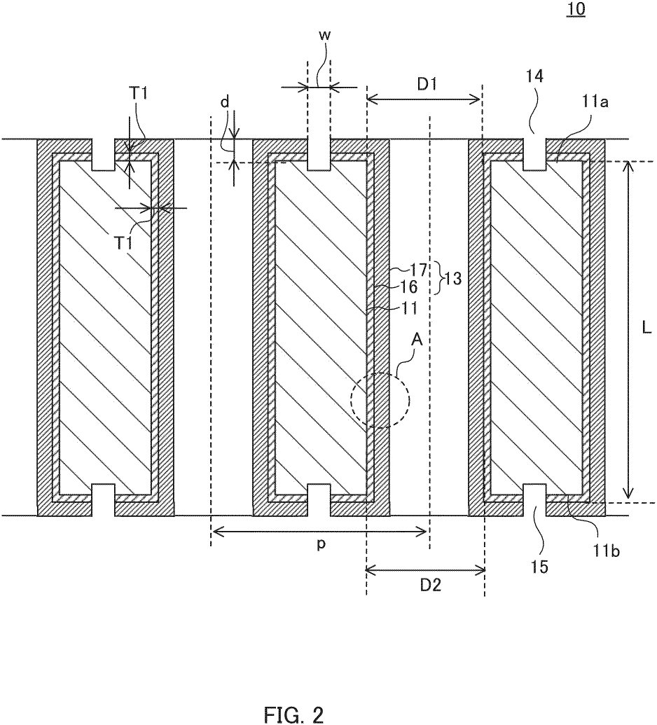

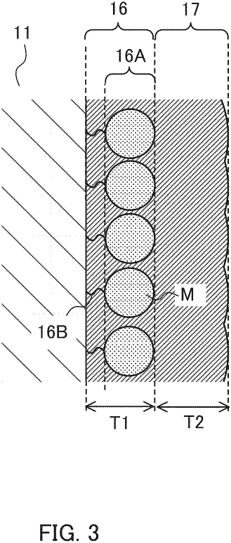

FIG. 1A is a plan view illustrating anisotropic conductive sheet 10 according to the present embodiment, and FIG. 1B is a partially enlarged sectional view of anisotropic conductive sheet 10 of FIG. 1A taken along line 1B-1B. FIG. 2 is an enlarged view of FIG. 1B. FIG. 3 is an enlarged schematic view of region A in FIG. 2.

As illustrated in FIGS. 1A and 1B, anisotropic conductive sheet 10 includes insulating layer 11 including a plurality of through holes 12, and a plurality of conductive layers 13 (see, for example, two conductive layers 13 indicated by symbols a1 and a2) respectively disposed so as to correspond to the plurality of through holes 12. Anisotropic conductive sheet 10 includes a plurality of hollows 12' surrounded by conductive layer 13.

In the present embodiment, the inspection object is preferably disposed at first surface 11a (one of the surfaces of anisotropic conductive sheet 10) of insulating layer 11.

### 1-1. Insulating Layer 11

Insulating layer 11 has first surface 11a located on one side in the thickness direction, second surface 11b located on the other side in the thickness direction, and the plurality of through holes 12 each extending between first surface 11a and second surface 11b (i.e., penetrating the sheet from first surface 11a to second surface 11b, see FIG. 1B).

Through hole 12 holds conductive layer 13 on its inner wall surface. In addition, through holes 12 increase the flexibility of insulating layer 11, allowing insulating layer 11 to be easily elastically deformed in the thickness direction.

Through hole 12 may have any shape, such as a columnar shape or a prismatic shape. In the present embodiment, through hole 12 has a columnar shape. In addition, the circle equivalent diameter (i.e., diameter of an equivalent circle) of through hole 12 in the cross section orthogonal to the axis direction may be constant or vary in the axial direction. The axial direction is a direction of a line connecting the center of the opening on the first surface 11a side and the center of the opening on second surface 11b side of through hole 12.

Circle equivalent diameter D1 of the opening of through hole 12 on first surface 11a side is not limited as long as center-to-center distance (pitch) p of the openings of the plurality of through holes 12 falls within a range described below. Circle equivalent diameter D1 is preferably 1 to 330 µm, or more preferably 3 to 55 µm (see FIG. 2), for example. Circle equivalent diameter D1 of the opening of through hole 12 on first surface 11a side is the circle equivalent diameter of the opening of through hole 12 as viewed along the axis direction of through hole 12 from first surface 11a side.

Circle equivalent diameter D1 of the opening of through hole 12 on first surface 11a side and circle equivalent diameter D2 of the opening of through hole 12 on second surface 11b side may be the same as or different from each other. When the circle equivalent diameter D1 of the opening of through hole 12 on first surface 11a side is different from circle equivalent diameter D2 of the opening of through hole 12 on second surface 11b side, the ratio of the diameters (circle equivalent diameter D1 of the opening on the first surface 11a side/circle equivalent diameter D2 of the opening on second surface 11b side) is, for example, 0.5 to 2.5, preferably 0.6 to 2.0, more preferably 0.7 to 1.5.

Center-to-center distance (pitch) p of the openings of the plurality of through holes 12 on first surface 11a side is not limited, and may be appropriately set in accordance with the pitch of the terminals of the inspection object (see FIG. 2). As an inspection object, a high bandwidth memory (HBM) has the pitch between the terminals of 55 µm, and a package on package (PoP) has the pitch between the terminals of 400 to 650 µm. Accordingly, center-to-center distance p of the openings of the plurality of through holes 12 may be 5 to 650 µm, for example. In particular, from the view point of eliminating the need for the alignment of the terminals of the inspection object (from the view point of achieving alignment free), it is preferable that center-to-center distance p of the openings of the plurality of through holes 12 on first surface 11a side is 5 to 55 µm. Center-to-center distance p of the openings of the plurality of through holes 12 on the first surface 11a side refers to the minimum value among the center-to-center distances of the openings of the plurality of through holes 12 on the first surface 11a side. The center of the opening of through hole 12 is the center of gravity of the opening. In addition, center-to-center distance p of the openings of the plurality of through holes 12 may be constant or vary in the axial direction.

The ratio (L/D1) of axial length L of through hole 12 (i.e., the thickness of insulating layer 11) and circle equivalent diameter D1 of the opening of through hole 12 on first surface 11a side is not limited, but is preferably 3 to 40 (see FIG. 2).

Insulating layer 11 has elasticity that allows the layer to be elastically deformed when a pressure is applied in the thickness direction of the layer. In other words, insulating layer 11 includes at least an elastic body layer, and may further include one or more additional layers as long as the elasticity is not impaired as a whole. In the present embodiment, insulating layer 11 itself is an elastic body layer.

### Elastic Body Layer

The elastic body layer comprises a cross-linked product of an elastomer composition (also referred to as “cross-linked elastomer composition”).

The glass transition temperature of the cross-linked elastomer composition in the elastic body layer is preferably -40° C. or less, more preferably -50° C. or less. The glass transition temperature can be measured in compliance with JIS K 7095:2012.

In addition, the coefficient of thermal expansion (CTE) of the cross-linked elastomer composition in the elastic body layer is not limited, but is preferably more than, for example, 60 ppm/K, and more preferably 200 ppm/K or more. The coefficient of thermal expansion can be measured in compliance with JIS K7197:1991.

The storage elastic modulus of the cross-linked elastomer composition in the elastic body layer at 25° C. is preferably 1.0×10⁷ Pa or less, more preferably 1.0×10⁵ to 9.0×10⁶ Pa. The storage elastic modulus of the elastic body layer can be measured in compliance with JIS K 7244-1:1998/IS06721-1:1994.

The glass transition temperature, the coefficient of thermal expansion and the storage elastic modulus of the cross-linked elastomer composition can be adjusted by the composition of the elastomer composition. In addition, the storage elastic modulus of the elastic body layer can be adjusted also by its form (for example, whether the layer is porous or not).

The elastomer composition may contain any elastomer as long as the elastomer has insulating properties, and the glass transition temperature, the coefficient of thermal expansion, and the storage elastic modulus of the cross-linked product of the elastomer composition fall within the above-described ranges. Preferred examples of the elastomer include silicone rubber, urethane rubber (urethane polymer), acrylic rubber (acrylic polymer), ethylene-propylene-diene copolymer (EPDM), chloroprene rubber, styrene-butadiene copolymer, acrylic nitrile-butadiene copolymer, polybutadiene rubber, natural rubber, polyester thermoplastic elastomer, olefin thermoplastic elastomer, and fluorine rubber. In particular, silicone rubber is preferred.

The elastomer composition may further contain a crosslinking agent, as necessary. The crosslinking agent is appropriately selected in accordance with the type of the elastomer. Examples of the crosslinking agent for the silicone rubber include addition reaction catalysts such as metals, metal compounds, and metal complexes (for example, platinum, platinum compounds, and their complexes) having catalytic activity for hydrosilylation reactions; and organic peroxides such as benzoyl peroxide, bis-2,4-dichlorobenzoyl peroxide, dicumylperoxide, and di-t-butyl peroxide. Examples of the crosslinking agent for acrylic rubber (acrylic polymer) include epoxy compounds, melamine compounds, and isocyanate compounds.

Examples of the cross-linked product of a silicone-based elastomer composition include an addition cross-linked product of a silicone-based elastomer compositions containing organopolysiloxane having a hydrosilyl group (SiH group), organopolysiloxane having a vinyl group, and an addition reaction catalyst; an addition cross-linked product of silicone rubber composition containing organopolysiloxane having a vinyl group, and an addition reaction catalyst; and a cross-linked product of a silicone-based elastomer composition containing organopolysiloxane having a SiCH3 group, and an organic peroxide curing agent.

From the viewpoint of, for example, facilitating the adjustment of the adhesion and the storage elastic modulus to fall within the above-described range, the elastomer composition may further include additional components such as a tackifier, a silane coupling agent, and a filler as necessary.

The elastic body layer may be porous, for example, from the viewpoint of facilitating the adjustment of the storage elastic modulus to fall within the above-described range. That is, porous silicone may be used.

### Additional Layer

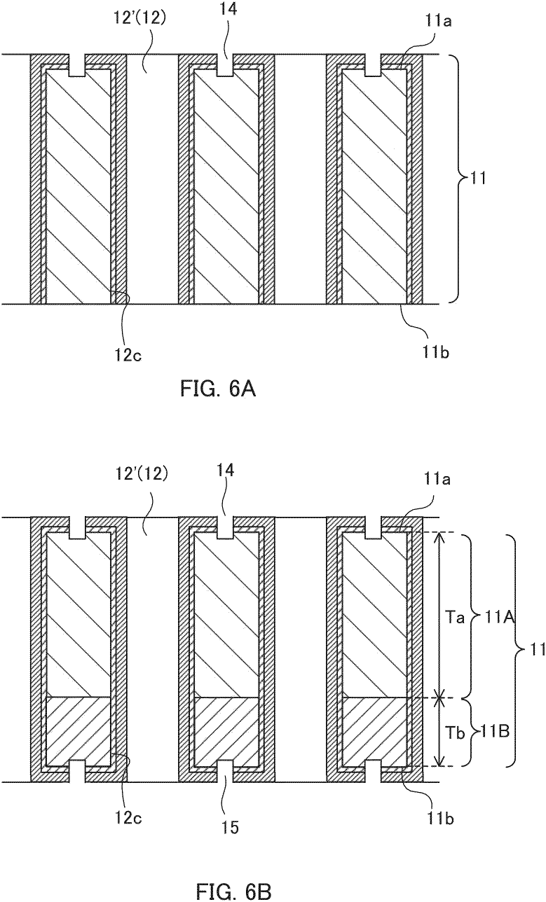

Insulating layer 11 may additionally include one or more layers other than the above-described layers as necessary. Examples of the additional layer include heat-resistant resin layers (see FIG. 6B described below) and adhesive layers.

### Pretreatment

The surface of insulating layer 11 (at least inner wall surface 12c of through hole 12) may be subjected to pretreatment from the viewpoint of increasing the adhesiveness with base layer 16.

The pretreatment is preferably treatment for giving a functional group that reacts with the bonding site of a sulfur-containing compound (contained in base layer 16). Examples of the functional group that reacts with the bonding site of a sulfur-containing compound include hydroxyl group, silanol group, epoxy group, vinyl group, amino group, carboxyl group, and isocyanate group. The functional group is preferably a hydroxyl group or a silanol group. For example, when the bonding site of the sulfur-containing compound contains an alkoxysilyl group, it is preferable that inner wall surface 12c of through hole 12 is provided with a hydroxyl group or a silanol group.

Examples of the pretreatment for giving the functional group as described above may be oxygen plasma treatment described below, treatment with a silane coupling agent, or a combination thereof.

The silane coupling agent may be a compound having an alkoxysilyl group that produces a silanol group (Si—OH) by hydrolysis, and an epoxy group, a vinyl group, or an amino group.

Examples of the silane coupling agent include epoxy silane coupling agents having an epoxy group, such as 3-glycidoxypropyltrimethoxysilane and 3-glycidoxypropyltriethoxysilane; vinyl silane coupling agents having an vinyl group, such as vinyltrimethoxysilane and vinylmethoxysilane; and amine-based silane coupling agents having an amino group in the molecule, such as γ-aminopropyltrimethoxysilane.

At least a part of the functional groups introduced into inner wall surface 12c of through hole 12 is preferably bonded by a reaction to at least a part of the functional groups of the binder (sulfur-containing compound) contained in base layer 16 described below. For example, the hydroxyl group or silanol group of inner wall surface 12c of through hole 12 and the alkoxysilyl group of the sulfur-containing compound are preferably condensed to form a silica bond, thereby forming a strong bond.

### Thickness

The thickness of insulating layer 11 is not limited as long as the insulating properties can be obtained in a non-conducting part, but may be, for example, 40 to 400 µm, preferably 100 to 300 µm.

### 1-2. Conductive Layer 13

Conductive layer 13 is disposed at least on inner wall surface 12c of through hole 12. In the present embodiment, conductive layer 13 is continuously disposed on inner wall surface 12c of through hole 12, on the first surface 11a around the opening of through hole 12, and on second surface 11b around the opening of through hole 12. A unit of conductive layer 13, indicated by symbol a1 or a2, functions as a conductive path (see FIG. 1B).

Conductive layer 13 includes base layer 16 and metal plating layer 17. Base layer 16 contains binder 16B and thin film 16A containing metal (herein also referred to as “metal-containing thin film”). Metal plating layer 17 is disposed so as to be in contact with metal-containing thin film 16A in base layer 16 (see FIGS. 2 and 3). FIG. 3 illustrates an example in which metal-containing thin film 16A contains metal nanoparticles M.

### 11. Base Layer 16

Base layer 16 is disposed between inner wall surface 12c of through hole 12 and metal plating layer 17. Base layer 16 increases the adhesiveness between inner wall surface 12c of through hole 12 and metal plating layer 17. In addition, base layer 16 allows for forming of metal plating layer 17 by an electrolytic plating method.

As described above, base layer 16 includes metal-containing thin film 16A and binder 16B.

### Metal-Containing Thin Film 16A

Metal-containing thin film 16A may be disposed on or at inner wall surface 12c of through hole 12 via binder 16B. Specifically, metal-containing thin film 16A may be a composite film of metal and binder 16B adsorbed to the metal via sulfur-containing group.

Any metal capable of imparting conductivity to metal-containing thin film 16A may be used as metal in the thin film. Preferred example of the metal include gold, silver, copper, platinum, tin, iron, cobalt, palladium, brass, molybdenum, and tungsten, permalloy, steel and alloys thereof. In particular, metal-containing thin film 16A preferably contains gold, silver, or platinum, and more preferably contains gold, from the excellent conductivity of the metals.

Metal-containing thin film 16A may have various forms depending on the method of forming base layer 16, and may or may not contain metal nanoparticles.

When metal-containing thin film 16A contains metal nanoparticles, the average particle size of the metal nanoparticles is not limited, but is preferably 1 to 100 nm. An average particle size of the metal nanoparticles within the above range increases the stability of the particles in water and maintains high dispersibility for a long period of time. From the same viewpoint, the average particle size of the metal nanoparticles is more preferably 10 to 30 nm. The average particle size of metal nanoparticles can be measured by a dynamic light scattering method or the use of a transmission electron microscope.

The thickness of metal-containing thin film 16A is not limited, but is preferably 10 to 200 nm, for example. A thickness of metal-containing thin film 16A of 10 nm or more is more likely to impart satisfactory conductivity to the surface of inner wall surface 12c of through hole 12. A thickness of 200 nm or less is less likely to impair the production efficiency. From the same viewpoint, the thickness of thin film 16A containing metal is more preferably 20 to 100 nm.

### Binder

At least a part of the binder is disposed between inner wall surface 12c of through hole 12 and film 16A containing metal. The binder may allow the metal in thin film 16A to be attached or adsorbed thereto.

The binder is a sulfur-containing compound having a thiol group, a sulfide group, or a disulfide group (i.e., organic compound having a sulfur-containing group). These sulfur-containing groups have a high affinity for metal, and the metal is easily attached or bonded to the groups. In other words, the binder bonds to inner wall surface 12c of through hole 12 at a site thereof other than the sulfur-containing group (preferably at a bonding site), and bonds to the metal (in the metal-containing thin film 16A) with the sulfur-containing group, thereby fixing metal-containing thin film 16A on or above inner wall surface 12c of through hole 12.

The sulfur-containing compound may have only one sulfur-containing group or may have two or more sulfur-containing groups. In particular, from the viewpoint of enhancing the metal trapping performance, the sulfur-containing compound preferably has two or more sulfur-containing groups.

In addition, the sulfur-containing compound may be a polymer. Examples of the polymer include polymers obtained by modifying a polymer of a compound having the above functional group (for example, a polymer of alkoxysilane) with a compound having a sulfur-containing group; and copolymers of monomers having the sulfur-containing group and monomers having the above functional group.

The sulfur-containing compound preferably further has a bonding site for bonding to inner wall surface 12c of through hole 12. The bonding site preferably has a functional group capable of bonding to the functional group on inner wall surface 12c of through hole 12 by an electrostatic attraction (for example, hydrogen bond) or a reaction (for example, a condensation reaction).

Examples of such a functional group include alkoxysilyl group (—SiRₙ (OR)_{3—n}, where n is an integer of 0 to 2), silanol group, amino group (—NH₂, —NHR, —NR₃), imino group, carboxyl group, carbonyl group, sulfonyl group, alkoxy group, hydroxyl group, and isocyanate group. In particular, when inner wall surface 12c of through hole 12 has a hydroxyl group or the like, a group capable of reacting with the hydroxyl group, such as alkoxysilyl group, silanol group, carboxyl group, and amino group are preferred. For example, when insulating layer 11 is a cross-linked product of a silicone-based elastomer, and subjected to a corona treatment to form a silanol group, the sulfur-containing compound preferably has an alkoxysilane group as a functional group at the bonding site.

The sulfur-containing compound may be a compound having no aromatic ring (namely, aliphatic compound) or a compound having an aromatic ring (aromatic compound).

The compound having no aromatic ring may have, for example, an alkylene group having 1 to 10 carbon atoms, preferably 2 to 8 carbon atoms. Examples of such a compound include alkyl disulfides such as thioctic acid, mercaptopentyl disulfide, and the compounds represented by the following Formula 1; and alkyl thiols such as amyl mercaptan, decanethiol, and the compounds represented by the following Formula 2.

$${\text{X}}_{3 \text{-m}} {\text{Me}}_{\text{m}} \text{Si-R-Y}$$

$${\text{X}}_{3 \text{-m}} {\text{Me}}_{\text{m}} {\text{Si-R-S}}_{\text{n}} {\text{-R-SiMe}}_{\text{m}} {\text{X}}_{\text{3-m}}$$

In Formulas 1 and 2,
m is 0 or 1,
n is an integer of 2 to 8,
X is an alkoxy group,
Me is a methyl group,
R is an ethylene group or a propylene group, and
Y is a thiol group.

Examples of the compounds represented by Formula 1 include 3-mercaptopropyltrimethoxysilane, 3-mercaptopropylmethyldimethoxysilane, and 3-mercaptopropyltriethoxysilane. Examples of the compounds represented by Formula 2 include bis(3-(triethoxysilyl)propyl) disulfide and bis(3-(triethoxysilyl)propyl) tetrasulfide.

The aromatic ring in the compound having an aromatic ring may be an aromatic hydrocarbon ring or an aromatic heterocycle. Examples of the compound having an aromatic ring include disulfides such as aminophenyl disulfide and 4,4’-dithiodipyridine; and thiols such as 6-mercaptopurine, 4-aminothiophenol, naphthalenethiol, 2-mercaptobenzimidazole, and triazine thiol compounds.

In particular, although it depends on the method of forming base layer 16, a sulfur-containing compound having an aromatic heterocycle is preferred, a compound having an aromatic heterocycle and two or more sulfur-containing groups is more preferred, and a triazine thiol compound is particularly preferred, for easily obtaining base layer 16 having excellent adhesiveness to inner wall surface 12c of through hole 12. It is not clear why triazine thiol compounds show particularly satisfactory adhesiveness; however, conceivable reasons therefor are, for example, as follows. The triazine ring is more likely to be packed between molecules thereby increasing the binder density; and the compound has a plurality of thiol groups per molecule thereby increasing the metal trapping performance.

The triazine thiol compound has a triazine skeleton and a thiol group. The thiol group is preferably bonded to a carbon atom in the triazine skeleton.

Examples of such a triazine thiol compound include compounds represented by the following formula 3.

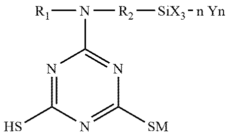

In Formula 3, R₁ represents a hydrogen atom or a monovalent hydrocarbon group. The monovalent hydrocarbon group may be a saturated hydrocarbon group or an unsaturated hydrocarbon group. The number of carbon atoms of the monovalent hydrocarbon group is not limited, but may be, for example, 1 to 10. In particular, R₁ is more preferably a hydrogen atom, CH₃-, C₂H₅—, n—C₃H₇—, CH₂═CHCH₂—, n—C₄H₉—, C₆H₅—, or C₆H₁₁—.

R₂ represents a divalent hydrocarbon group. The divalent hydrocarbon group may have an atom or a functional group in addition to hydrogen atoms and carbon atom(s). For example, R₂ may be a divalent hydrocarbon group having a sulfur atom, a nitrogen atom, a carbamoyl group, or a urea group. The number of carbon atoms of the divalent hydrocarbon group is not limited, but may be, for example, 2 to 10. In particular, R₂ is preferably, for example, an ethylene group, a propylene group, a hexylene group, a phenylene group, a biphenylene group, a decanyl group, —CH₂CH₂—S—CH₂CH₂—, —CH₂CH₂CH₂—S—CH₂CH₂CH₂—, —CH₂CH₂—NH—CH₂CH₂CH₂—, —(CH₂CH₂)₂—N—CH₂CH₂CH₂—, —CH₂—Ph—CH₂—, —CH₂CH₂O—CONH—CH₂CH₂CH₂—, or —CH₂CH₂NHCOCNHCH₂CH₂CH₂—.

X represents a hydrogen atom or a monovalent hydrocarbon group. The number of carbon atoms of the monovalent hydrocarbon group is not limited, but may be, for example, 1 to 5. In particular, X is preferably a hydrogen atom, a methyl group, an ethyl group, a propyl group, or a butyl group.

Y represents an alkoxy group. The number of carbon atoms of the alkoxy group is 1 to 5. In particular, Y is preferably a methoxy group, an ethoxy group, a propoxy group, or a butoxy group.

n is an integer of 1 to 3, preferably 3.

M represents an alkali metal, preferably Li, Na, K or Cs.

Other examples of triazine-thiol compounds include triazine compounds represented by following Formulas 4A-1 to 4A-3 and reaction products of the triazine-thiol compounds and organic compounds (having a bonding site and) capable of reacting with or being adsorbed to the triazine-thiol compound.

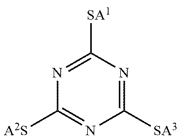

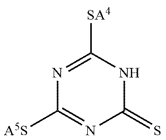

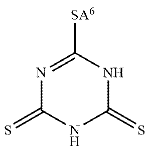

In Formulas 4A-1 to 4A-3,

Each of A¹ to A⁶ represents a hydrogen atom, Li, Na, K, Rb, Cs, Fr, or a substituted or unsubstituted ammonium, and is preferably a hydrogen atom. A¹ to A⁶ may be the same as or different to each other.

The organic compound that can react with or be adsorbed to the triazine compound represented by any one of above Formulas 4A-1 to 4A-3 preferably has the above-described bonding site. Such an organic compound may be, for example, a compound having a functional group selected from the group consisting of an alkoxysilyl group, an amino group (—NH₂, —NHR, —NR₃), a carboxyl group, a hydroxyl group, and an isocyanate group. Specifically, the organic compound may be a compound represented by any one of following Formulas 4B-1 to 4B-10.

NHR²—R¹—NHR³ ... Formula 4B-1

In Formula 4B-1,
R¹ represents a substituted or unsubstituted phenylene group, a xylylene group, an azo group, an organic group having an azo group, a divalent benzophenone residue, a divalent phenyl ether residue, an alkylene group, a cycloalkylene group, a pyridylene group, an ester residue, a sulfon group, or carbonyl group; and
R² and R³ each represent a hydrogen atom or an alkyl group.

Examples of the compound represented by Formulas 4B-1 include diaminobenzene, diaminoazobenzene, diaminobenzoic acid, diaminobenzophenone, hexamethylenediamine, phenylenediamine, xylylenediamine, 1,2-diaminoethane, 1,3-diaminopropane, 1,4-diaminobutane, 1,6-diaminohexane, 1,7-diaminoheptane, 1,8-diaminooctane, 1,9-diaminononane, 1,10-diaminodecane, 1,12-diaminododecane, 1,2-diaminocyclohexane, diaminodiphenyl ether, N,N′-dimethyltetramethylenediamine, diaminopyridine, diethylenetriamine, triethylenetetramine, tetraethylenepentamine, m-hexamethylene-triamine, benzidine, 3,3'-dimethyl-4,4'-diamino-dicyclohexylmethane, diaminodiphenylmethane, diaminodiphenylsulfone, and m-aminobenzylamine.

R⁴—NH₂ ... Formula 4B-2

In Formula 4B-2, R⁴ represents a phenyl group, a biphenylyl group, a substituted or unsubstituted benzyl group, an organic group having an azo group, a benzoylphenyl group, a substituted or unsubstituted alkyl group, a cycloalkyl group, an acetal residue, a pyridyl group, an alkoxycarbonyl group, or an organic group having an aldehyde group.

Examples of the compound represented by Formulas 4B-2 include methylamine, ethylamine, propylamine, butylamine, pentylamine, hexylamine, octylamine, nonylamine, n-decylamine, n-undecylamine, n-dodecylamine, n-heptylamine, n-nonylamine, stearylamine, cyclopropylamine, cyclohexylamine, o-aminodiphenyl, 1-methylbutylamine, 2-ethylbutylamine, 2-ethylhexylamine, 2-phenylethylamine, benzylamine, o-methoxybenzylamine, aminoacetaldehyde dimethyl acetal, aminoacetaldehyde diethyl acetal, and aminophenol.

R⁵—NH—R⁶ ... Formula 4B-3

In Formula 4B-3, R⁵ and R⁶ each represent a phenyl group, an organic group having an azo group, a benzoylphenyl group, an alkyl group, a pyridyl group, an alkoxycarbonyl group, an aldehyde group, a benzyl group, or an unsaturated group.

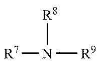

In Formula 4B-4, R⁷, R⁸ and R⁹ each represent a phenyl group, a benzyl group, an organic group having an azo group, a benzoylphenyl group, a substituted or unsubstituted alkyl group, a pyridyl group, an alkoxycarbonyl group, an aldehyde group, or a nitroso group.

Examples of the compounds represented by Formulas 4B-3 and 4B-4 include 1,1-dimethoxytrimethylamine, 1,1-diethoxytrimethylamine, N-ethyldiisopropylamine, N-methyldiphenylamine, N-nitrosodiethylamine, N-nitrosodiphenylamine, N-phenyldibenzylamine, triethylamine, benzyldimethylamine, aminoethylpiperazine, 2,4,6-tris(dimethylaminemethyl)phenol, tetramethylguanidine, and 2-methylaminomethylphenol.

OH—R¹⁰—OH ... Formula 4B-5

In Formula 4B-5, R¹⁰ represents a substituted or unsubstituted phenylene group, an organic group having an azo group, a divalent benzophenone residue, an alkylene group, a cycloalkylene group, a pyridylene group, or an alkoxycarbonyl group.

Examples of the compound represented by Formula 4B-5 include dihydroxybenzene, dihydroxyazobenzene, dihydroxybenzoic acid, dihydroxybenzophenone, 1,2-dihydroxyethane, 1,4-dihydroxybutane, 1,3-dihydroxypropane, 1,6-dihydroxyhexane, 1,7-dihydroxypentane, 1,8-dihydroxyoctane, 1,9-dihydroxynonane, 1,10-dihydroxydecane, 1,12-dihydroxydodecane, and 1,2-dihydroxycyclohexane.

R¹¹—X¹—R¹² ... Formula 4B-6

In Formula 4B-6,
R¹¹ and R¹² each represent an unsaturated group, and
X¹ represents a divalent maleic acid residue, a divalent phthalic acid residue, or a divalent adipic acid residue.

Examples of the compound represented by Formula 4B-6 include diallyl chlorendate, diallyl maleate, diallyl phthalate, diallyl adipate.

R¹³-X² ... Formula 4B-7

In Formula 4B-7,
R¹³ represents an unsaturated group, and
X² represents a substituted or unsubstituted phenyl group, an alkyl group, an amino acid residue, an organic group having a hydroxyl group, a cyanuric acid residue, or an alkoxycarbonyl group.

R¹⁴—N═CO ... Formula 4B-8

In Formula 4B-8,

R¹⁴ represents a substituted or unsubstituted phenyl group, a naphthyl group, a substituted or unsubstituted alkyl group, a benzyl group, a pyridyl group, or an alkoxycarbonyl group.

Examples of the compounds represented by Formulas 4B-7 and 4B-8 include allyl methacrylate, 1-allyl-2-methoxybenzene, 2-allyloxyethanol, 3-allyloxy-1,2-propanediol, 4-allyl-1,2-dimethoxybenzene, allyl acetate, allyl alcohol, allyl glycidyl ether, allyl heptanoate, allyl isophthalate, allyl isovalerate, allyl methacrylate, allyl n-butyrate, allyl n-caprate, allyl phenoxyacetate, allyl propionate, allylbenzene, o-allylphenol, triallyl cyanurate, and triallylamine.

R¹⁵—X³ ... Formula 4B-9

In Formula 4B-9,
R¹⁵ represents a phenyl group, a substituted or unsubstituted alkyl group, an alkoxycarbonyl group, an amide group, or a vinyl group, and
X³ represents an acrylic acid residue.

Examples of the compound represented by Formula 4B-9 include 2-(dimethylamino)ethyl acrylate, 2-acetamidoacrylic acid, 2-ethylhexyl acrylate, 2-hydroxyethyl acrylate, acrylamide, N-methylolacrylamide, ethyl acrylate, butyl acrylate, isobutyl acrylate, methacrylic acid, methyl 3-methoxyacrylate, stearyl acrylate, vinyl acrylate, and 3-acrylamide-N,N-dimethylpropylamine.

R¹⁶—CO—R¹⁷ ... Formula 4B-10

In Formula 4B-10, R¹⁶ and R¹⁷ each represent a phenyl group, an alkyl group, an alkoxycarbonyl group, an amide group, or a vinyl group.

Examples of the compound represented by Formula 4B-10 include 1,2-cyclohexanedicarboxylic anhydride, 2-chloromaleic anhydride, 4-methylphthalic anhydride, benzoic anhydride, butyric anhydride, oxalic acid, phthalic anhydride, maleic anhydride, hexahydrophthalic anhydride, pyromellitic anhydride, trimellitic anhydride, trimellitic anhydride dolichol, methylnadic anhydride, crotonic anhydride, dodecylsuccinic anhydride, dichloromaleic anhydride, poly(azelaic anhydride), and polysebacic anhydride.

Binder 16B may be a conductive compound.

Base layer 16 may further contain one or more additional components, as necessary. Examples of the additional component may include components derived from a reducing agent contained in the electroless plating solution, or plating components in metal plating layer 17. Base layer 16 is preferably substantially free of nickel from the viewpoint of preventing excessive increase in the hardness. The term “substantially free of nickel” means that the content of nickel or a compound thereof is 10 mass% or less, preferably 5 mass% or less, based on base layer 16. With the content in the above range, the hardness of base layer 16 is less likely to increase, thus the layer is less likely to be peeled off when the sheet is elastically deformed in the thickness direction.

The present embodiment shows the example in which base layer 16 contains metal-containing thin film 16A and binder 16B (see FIG. 3A), but the present invention is not limited thereto. As the boundary between metal-containing thin film 16A and binder 16B is not always clear, what is essential is that the entire base layer 16 is a layer contains a metal and a binder (organic-inorganic composite layer). For example, in base layer 16, which contains a metal and a binder, the metal may be mainly present in the surface layer portion of base layer 16 (namely, the surface layer portion in contact with metal plating layer 17). In other words, base layer 16 may include (from the inner wall surface 12c side of through hole 12) a region having a relatively small amount of metal and a region having a relatively large amount of metal.

### Thickness

Base layer 16 may have any thickness as long as inner wall surface 12c of through hole 12 can satisfactorily adhere to metal plating layer 17. The thickness of base layer 16 depends on, for example, the method of forming the layer, but is preferably 10 to 500 nm, for example. A thickness of base layer 16 of 10 nm or more is more likely to allow inner wall surface 12c of through hole 12 to satisfactorily adhere to metal plating layer 17. A thickness of base layer 16 of 500 nm or less is more likely to prevent the peeling of base layer 16 even when anisotropic conductive sheet 10 is repeatedly and elastically deformed in the thickness direction. From the same viewpoint, the thickness of base layer 16 is more preferably 30 to 300 nm.

In the present embodiment, thickness T1 of base layer 16 on first surface 11a (or second surface 11b) refers to the thickness of base layer 16 in the thickness direction of insulating layer 11, and thickness T1 of base layer 16 on inner wall surface 12c refers to the thickness of base layer 16 in the direction orthogonal to the thickness direction of insulating layer 11 (see FIG. 2).

The thickness of base layer 16 can be measured from a cross-sectional image taken by a scanning electron microscope.

Specifically, the cross section of anisotropic conductive sheet 10 along the thickness direction is observed with the scanning electron microscope. A region corresponding to base layer 16 is then specified, and the thickness thereof is measured. For example, in metal-containing thin film 16A containing metal nanoparticles (for example, metal-containing thin film formed by the a method with the use of metal nanoparticles (also referred to as “metal nanoparticle method”)), a line connecting the outer edges of the metal nanoparticles in the secondary electron image can be determined as the boundary between base layer 16 and metal plating layer 17. In addition, in metal-containing thin film 16A that does not contain metal nanoparticles (metal-containing thin film formed by a molecular bonding method), the outer edge of a region containing sulfur atoms in the characteristic X-ray image obtained by, for example, SEM-EDX or TEM-EDX can be determined as the boundary.

Thickness T1 of base layer 16 is preferably less than thickness T2 of metal plating layer 17. Specifically, the ratio of thickness T1 of base layer 16 to the total of thickness T1 of base layer 16 and thickness T2 of metal plating layer 17, namely ratio T1/(T1+T2), is preferably 0.0025 to 0.5 (see FIG. 3). A ratio T1/(T1+T2) of 0.0025 or more is more likely to allow inner wall surface 12c of through hole 12 to satisfactorily adhere to metal plating layer 17. A ratio T1/(T1+T2) of 0.5 or less is more likely to impart satisfactory conductivity. From the same viewpoint, ratio T1/(T1+T2) is more preferably 0.005 to 0.2.

### 12. Metal Plating Layer 17

Metal plating layer 17 is a layer constituting the main part of conductive layer 13, and disposed so as to be in contact with metal-containing thin film 16A of base layer 16. Metal plating layer 17 may be a layer formed by an electrolytic plating method starting from metal-containing thin film 16A of base layer 16.

The volume resistivity of the material constituting metal plating layer 17 is not limited as long as satisfactory conductivity can be obtained, but is, for example, preferably 1.0 × 10⁻⁴ Ω·m or less, more preferably 1.0 × 10⁻⁶ to 1.0 × 10⁻⁹ Ω·m. The volume resistivity of the material constituting metal plating layer 17 can be measured by the method described in ASTM D 991.

Any metal that can be formed on or above base layer 16 by electrolytic plating or the like may be used for metal plating layer 17. Example of the metal in metal plating layer 17 may be the same as those given as examples of the metal in metal-containing thin film 16A of base layer 16. The metal in metal-containing thin film 16A of base layer 16 may be the same as or different from the metal in metal plating layer 17. From the viewpoint of further increasing the adhesiveness between base layer 16 and metal plating layer 17, the metal in metal-containing thin film 16A of base layer 16 is preferably the same as the metal in metal plating layer 17.

### Thickness

The thickness of metal plating layer 17 may be any value as long as satisfactory conductivity can be obtained, through holes 12 are not blocked, and the metal plating layer is not peeled off due to elastic deformation of the sheet. Specifically, metal plating layer 17 preferably has a thickness such that the thickness ratio (T1/(T1+T2)) satisfies the above range. The thickness is preferably 0.2 to 4 µm, for example. A thickness of metal plating layer 17 of 0.2 µm or more is more likely to impart satisfactory conductivity. A thickness of metal plating layer 17 of 4 µm or less is more likely to prevent peeling off of metal plating layer 17 caused by the elastic deformation of the sheet, and prevent the damage of the terminals of an inspection object caused by the contact with metal plating layer 17. From the same viewpoint, the thickness of metal plating layer 17 is more preferably 0.5 to 2 µm, for example.

In the present embodiment, the thickness of metal plating layer 17 on first surface 11a (or second surface 11b) refers to the thickness of metal plating layer 17 in the thickness direction of insulating layer 11, and the thickness of metal plating layer 17 on inner wall surface 12c refers to the thickness of metal plating layer 17 in the direction orthogonal to the thickness direction of insulating layer 11, in the same manner as base layer 16.

### 13. Common Matter

The circle equivalent diameter of hollow 12’ surrounded by conductive layer 13 on first surface 11a side is obtained by subtracting a length corresponding to the thickness of conductive layer 13 from circle equivalent diameter D1 of the opening of through hole 12 on first surface 11a side. The circle equivalent diameter may be, for example, 1 to 330 µm.

### 1-3. First Groove Part 14 and Second Groove Part 15

First groove part 14 and second groove part 15 are grooves (valley lines) respectively formed in one surface and the other surface of anisotropic conductive sheet 10. Specifically, first groove part 14 is disposed at first surface 11a and between conductive layers 13 for insulating the conductive layers from each other. Second groove part 15 is disposed at second surface 11b and between conductive layers 13 for insulating the conductive layers from each other.

The cross-sectional shape of first groove part 14 (or second groove part 15) in the direction orthogonal to the extending direction is not limited, and may be a rectangular shape, a semicircular shape, a U shape, or a V shape. In the present embodiment, the cross-sectional shape of first groove part 14 (or second groove part 15) is a rectangular shape.

Width w and depth d of first groove part 14 (or second groove part 15) are preferably set to fall within a range in such a way that when anisotropic conductive sheet 10 is pressed in the thickness direction, conductive layer 13 on one side and conductive layer 13 on the other side with first groove part 14 (or second groove part 15) therebetween do not make contact with each other.

Specifically, when anisotropic conductive sheet 10 is pressed in the thickness direction, conductive layer 13 on one side and conductive layer 13 on the other side with first groove part 14 (or second groove part 15) therebetween tend to approach and make contact with each other. Therefore, width w of first groove part 14 (or second groove part 15) is preferably more than the thickness of conductive layer 13, and is preferably 2 to 40 times the thickness of conductive layer 13.

Width w of first groove part 14 (or second groove part 15) is the maximum width in the direction orthogonal to the extending direction of first groove part 14 (or second groove part 15) in first surface 11a (or second surface 11b) (see FIG. 2).

Depth d of first groove part 14 (or second groove part 15) may be the same as, or more than the thickness of conductive layer 13. That is, the deepest part of first groove part 14 (or second groove part 15) may be located at first surface 11a of insulating layer 11, or located inside insulating layer 11. In particular, from the viewpoint of easily setting the thickness to fall within a range such that conductive layer 13 on one side and conductive layer 13 on the other side with first groove part 14 (or second groove part 15) placed therebetween do not contact with each other, depth d of first groove part 14 (or second groove part 15) is preferably more than the thickness of conductive layer 13, more preferably 1.5 to 20 times the thickness of conductive layer 13 (see FIG. 2).

Depth d of first groove part 14 (or second groove part 15) refers to the depth from the surface of conductive layer 13 to the deepest part of the groove part in the direction parallel to the thickness direction of insulating layer 11 (see FIG. 2).

Width w and depth d of first groove part 14 and second groove part 15 may be the same as or different from each other.

### 1-4. Effects

In anisotropic conductive sheet 10 of the present embodiment, conductive layer 13 includes base layer 16 disposed between inner wall surface 12c of through hole 12 and metal plating layer 17. Base layer 16 contains a binder, which allows inner wall surface 12c of through hole 12 to satisfactorily adhere to metal plating layer 17 while giving appropriate flexibility. This configuration is more likely to prevent the peeling of metal plating layer 17 even when anisotropic conductive sheet 10 is repeatedly and elastically deformed in the thickness direction by pressurization and depressurization during electrical testing. Therefore, satisfactory electrical connection between the substrate of an electrical testing apparatus and an inspection object becomes possible.

In addition, anisotropic conductive sheet 10 in the present embodiment includes conductive layer 13 not only at inner wall surface 12c of through hole 12, but also at first surface 11a and second surface 11b of insulating layer 11 (or the surfaces of anisotropic conductive sheet 10). In this manner, during electrical testing, electrical contact can be reliably performed when the anisotropic conductive sheet is placed between the electrode of the inspection substrate and the terminal of the inspection object and pressurized.

### 2. Method for Producing Anisotropic Conductive Sheet

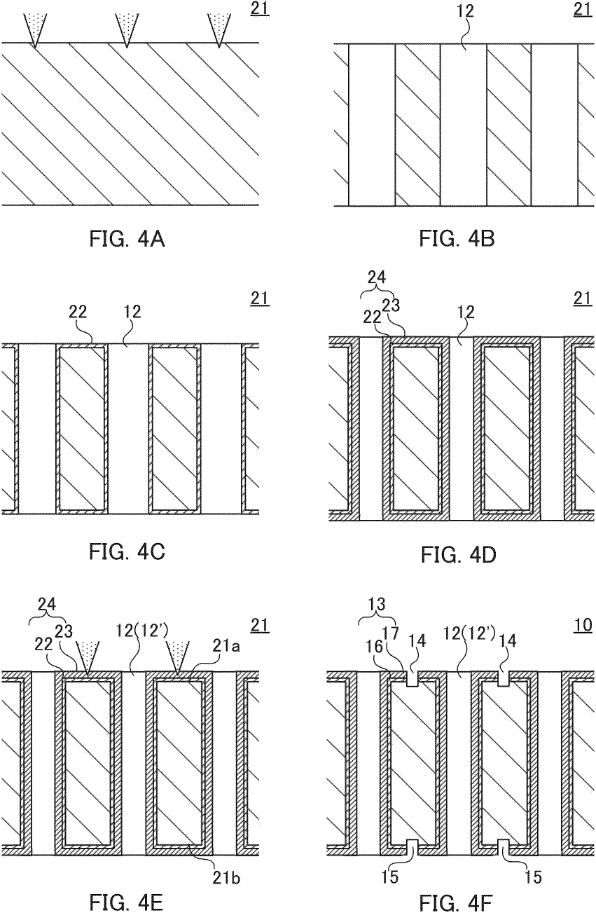

FIGS. 4A to 4F are schematic cross-sectional views illustrating a method for producing anisotropic conductive sheet 10 according to the present embodiment.

Anisotropic conductive sheet 10 according to the present embodiment can be produced, for example, by the following steps: 1) preparing insulating sheet 21 (see FIG. 4A); 2) forming a plurality through holes 12 in insulating sheet 21 (see FIG. 4B); 3) forming base layer 22 on the surface of insulating sheet 21, in which plurality of through holes 12 are formed (see FIG. 4C); 4) forming metal plating layer 23 on or above base layer 22 to obtain conductive layer 24 (see FIG. 4D), and 5) removing a part of insulating sheet 21 on the first surface 21a side and a part of insulating sheet 21 on the second surface 21b side (see FIG. 4E) to obtain plurality of conductive layers 13 (see FIG. 4F).

### Step 1): Preparing Insulating Sheet

First, insulating sheet 21 is prepared. In the present embodiment, insulating sheet 21 containing a cross-linked product (elastic body layer) of the silicone-based elastomer composition is prepared.

### Step 2): Forming Through Holes

Next, plurality of through holes 12 are formed in insulating sheet 21.

Through hole 12 can be formed by any method. Examples of the method include methods that mechanically form holes (for example, press working and punching) and laser processing methods. In particular, it is more preferable to form through holes 12 by a laser processing method, which can form fine through holes 12 with high shape accuracy (see FIG. 4A).

The medium of the laser is not limited, and may be an excimer laser, a carbon dioxide gas laser, or a YAG laser. The pulse width of the laser is not limited, and any one of the following may be used: picosecond laser, nanosecond laser, and femtosecond laser. A femtosecond laser, which can easily drill a resin with high accuracy, is thus preferred.

During laser processing, the diameter of the opening of through hole 12 tends to become large at the laser irradiation surface, where the irradiation time of laser is longest, of insulating layer 11. In other words, a through hole tends to have a tapered shape whose the opening diameter increases from the inside of insulating layer 11 toward the laser irradiation surface. From the viewpoint of lessening such a tapered shape, the laser processing may be performed by using insulating sheet 21 that further includes a sacrificial layer (not illustrated) at the surface to be irradiated with laser. For laser processing insulating sheet 21 that includes a sacrificial layer, a method similar to the method disclosed in, for example, WO2007/23596 may be used.

### Step 3): Forming Base Layer

Next, one continuous base layer 22 is formed on the entire surface of insulating sheet 21, in which plurality of through holes 12 are formed (see FIG. 4C). Specifically, on insulating sheet 21, base layer 22 is continuously formed on inner wall surface 12c of each through hole 12 and first surface 21a and second surface 21b around the openings of the through hole.

Base layer 22 can be formed by any method. For example, the following method may be used: a method (molecular bonding method) in which insulating sheet 21 is brought into contact with a solution containing a binder to attach the binder to insulating sheet 21, and insulating sheet 21 is then further brought into contact with a solution including metal ions dissolved therein to deposit a metal thin film on the binder attached to insulating sheet 21; or a method (metal nanoparticle method) in which base layer 22 is formed by bringing insulating sheet 21, in which plurality of through holes 12 are formed, into contact with a dispersion liquid containing metal nanoparticles and a binder.

### Molecular Bonding Method

In the molecular bonding method, base layer 16 is formed by the following steps: A) bringing insulating sheet 21 into contact with a solution containing a binder to apply the binder to insulating sheet 21; and further, B) bringing insulating sheet 21, with the binder applied thereon, into contact with a solution including metal ions dissolved therein to deposit a metal thin film on or above the binder of insulating sheet 21. Through the steps, base layer 22 including metal-containing thin film 16A can be obtained.

### Step A): Applying Binder

First, insulating sheet 21, in which plurality of through holes 12 are formed, is brought into contact with the solution containing a binder. As a result, the binder is applied to the surface of insulating sheet 21.

The solution containing the binder is an aqueous solution containing the binder, and may further contain a water-soluble organic solvent or the like, as necessary. As the binder, the above-described binder can be used. In particular, the binder to be used in this method is preferably a triazine thiol compound. The content of the binder is not limited, but may be, for example, about 0.01 to 10 mass% based on the aqueous solution from the viewpoint of facilitating entering of through hole 12.

Insulating sheet 21 may be brought into contact with the solution containing the binder by spraying or applying the above solution to insulating sheet 21 or immersing the insulating sheet in the above solution. In particular, it is preferable to immerse insulating sheet 21 in the above solution.

Insulating sheet 21 is then taken out of the solution and dried. The drying may be heat drying. The conditions for immersing and drying may be the same as those described below.

For improving the adhesion between insulating sheet 21 and the binder, it is preferable to introduce or bond functional groups such as hydroxyl groups to the surface of insulating sheet 21 and inner wall surface 12c of through hole 12 before insulating sheet 21 is brought into contact with the solution containing the binder (see step 6): Pretreating below).

### Step B): Electroless Plating

Next, insulating sheet 21, to which the binder is applied, is then brought into contact with a solution (electroless plating solution) including metal ions dissolved therein to perform electroless plating. As a result, a metal thin film is deposited on or above the binder applied to insulating sheet 21.

From the viewpoint of facilitating the formation of thin film 16A containing metal, an activation treatment is preferably performed before the electroless plating.

### Activation Treatment

Insulating sheet 21 is immersed in an activating liquid to activate a sulfur-containing group (for example, a thiol group) of the binder.

The activation solution to be used may be an aqueous solution containing a palladium salt, a gold salt, a platinum salt, a silver salt, or a tin salt such as tin chloride, and an amine complex. When insulating sheet 21 having, for example, -SH and -S-S- groups is immersed in this aqueous solution, metal such as palladium, platinum, or silver is deposited on and chemically bonded (adheres) to these groups. The metal thus is not easily removed even when washing is performed.

### Electroless Plating

Next, obtained insulating sheet 21 is brought into contact with an electroless plating solution. The sheet may be brought into contact with the electroless plating solution, for example, by spraying or applying the electroless plating solution to insulating sheet 21, or by immersing insulating sheet 21 in the electroless plating solution. In particular, it is preferable to immerse insulating sheet 21 in the electroless plating solution.

The electroless plating solution contains a metal salt and a reducing agent, and may further contain one or more auxiliary components, such as a pH adjuster, a buffer, a complexing agent, an accelerator, a stabilizer, and an improving agent, as necessary.

Examples of the metal in the metal salt include gold, silver, copper, cobalt, iron, palladium, platinum, brass, molybdenum, tungsten, permalloy, steel, nickel, and alloys thereof. These metal salts may be used individually or in a mixture thereof.

Specific examples of the metal salt include KAu(CN)₂, KAu(CN)₄, Na₃Au(SO₃)₂, Na₃Au(S₂O₃)₂, NaAuCl₄, AuCN, Ag(NH₃)₂NO₃, AgCN, CuSO₄.5H₂O, CuEDTA, NiSO₄·7H₂O, NiCl₂, Ni(OCOCH₃)₂, CoSO₄, CoCl₂, SnCl₂•7H₂O, and PdCl₂. The concentration of the metal salt may usually be in the range of 0.001 to 1 mol/L.

The reducing agent has the effect of reducing the above metal salt to form a metal. Examples of the reducing agent include KBH₄, NaB, NaH₂PO₂, (CH₃)₂NH•BH₃, CH₂O, NH₂NH₂, hydroxylamine salts, and N,N-ethylglycine. The concentration of the reducing agent may usually be in the range of 0.001 to 1 mol/L.

In addition to the above components, the electroless plating solution may further contain one or more additional auxiliary components for the purpose of extending the durability of the electroless plating solution and/or increasing the reduction efficiency. Examples of the additional auxiliary component include basic compounds, inorganic salts, organic acid salts, citrates, acetates, borates, carbonates, ammonia hydroxide, EDTA, diaminoethylene, sodium tartrate, ethylene glycol, thiourea, triazinethiol, and triethanolamine. The concentration of the additional auxiliary component may usually be in the range of 0.001 to 0.1 mol/L.

The immersing conditions may be any conditions as long as base layer 22 capable of giving conductivity can be formed. For example, the immersion temperature may be 20 to 50° C., and the immersion time may be 30 minutes to 24 hours.

Insulating sheet 21 is then taken out of the electroless plating solution and dried. The drying may preferably be heat drying. The heat drying is preferably performed in a nitrogen gas or argon gas atmosphere from the viewpoint of minimizing the oxidation of the metal. The heating temperature is preferably set so as to not damage insulating sheet 21. For example, the heat drying is performed in a temperature range of, for example, 50 to 200° C. for 1 to 180 minutes.

### Metal Nanoparticle Method

In the metal nanoparticle method, insulating sheet 21, in which plurality of through holes 12 are formed, is brought into contact with a dispersion liquid containing metal nanoparticles and a binder. In this manner, the metal nanoparticles can be attached to the surface of insulating sheet 21, in which plurality of through holes 12 are formed, via binder 16B, thereby forming metal-containing thin film 16A containing the metal nanoparticles.

The dispersion liquid containing metal nanoparticles and a binder may be obtained, for example, by mixing a dispersion liquid of metal nanoparticles and the above-described binder.

The dispersion liquid of metal nanoparticles may be obtained by mixing a metal salt containing a metal corresponding to metal-containing thin film 16A, a reducing agent, and water, and as necessary, under heating. In other words, the same metal salt or reducing agent as that used in the above-described electroless plating solution may be used in the metal nanoparticle method.

As the binder, the above-described binder can be used. In particular, the binder to be used in this method is preferably an alkyl disulfide having a bonding site (for example, thioctic acid or mercaptopentyl disulfide).

The dispersion liquid may further contain one or more components in addition to water, as necessary. Examples of the additional component include water-soluble solvents (for example, alcohols such as ethanol and ketones such as acetone).

The sheet may be brought into contact with the dispersion liquid by spraying or applying the dispersion liquid to insulating sheet 21, or by immersing insulating sheet 21 in the dispersion liquid, in the same manner as described above. It is preferable to immerse insulating sheet 21 in the dispersion liquid. The immersing conditions may be the same as the immersing conditions in the electroless plating in the above method.

Insulating sheet 21 is then taken out of the dispersion liquid and dried. The drying may preferably be heat drying. The drying conditions may be the same as the drying conditions in the above method.

### Step 4): Forming Metal Plating Layer

Next, metal plating layer 23 is formed on or above obtained base layer 22 (see FIG. 4D).

Metal plating layer 23 may be formed by any method such as an electroless plating method or an electrolytic plating method. Base layer 22 includes a metal-containing thin film in the surface layer portion thereof (see metal-containing thin film 16A in FIG. 3) and has conductivity. Therefore, metal plating layer 23 is preferably formed by an electrolytic plating method starting from the metal-containing thin film. As a result, conductive layer 24 including base layer 22 and metal plating layer 17 can be formed (see FIG. 4D).

When the conductivity of metal-containing thin film 16A is insufficient, the following procedure is also possible: a metal plating thin film is additionally formed by an electroless plating method, and then metal plating layer 23 is formed by an electrolytic plating method. Components such as a metal salt and a reducing agent to be used in the electroless plating solution in the electroless plating method may be the same as in the above-described electroless plating solution.

### Step 5): Forming Conductive Layer

Then, plurality of first groove parts 14 and plurality of second groove parts 15 are formed at the first surface and the second surface of insulating sheet 21, respectively (see FIG. 4F). As a result, conductive layer 24 becomes into plurality of conductive layers 13 individually provided for corresponding through holes 12 (see FIG. 4F).

Plurality of first groove parts 14 and plurality of second groove parts 15 may be formed by any method. For example, it is preferable to form plurality of first groove parts 14 and plurality of second groove parts 15 by a laser processing method. In the present embodiment, in first surface 11a (or second surface 11b), plurality of first groove parts 14 (or plurality of second groove parts 15) may be formed in a grid pattern (see FIG. 1A).

### Additional Step

The method for producing anisotropic conductive sheet 10 may additionally include one or more steps, as necessary. For example, between steps 2) and 3), it is preferable to further perform step 6) of pretreating insulating sheet 21, in which plurality of through holes 12 are formed.

### Step 6): Pretreating

Insulating sheet 21, in which plurality of through holes 12 are formed, is preferably subjected to pretreatment for facilitating the formation of base layer 22.

Specifically, before insulating sheet 21 is brought into contact with the solution containing the binder in step 3) of forming a base layer, it is preferable to introduce or bond functional groups such as hydroxyl groups to the surface of insulating sheet 21 and inner wall surfaces 12c of the through holes for improving the adhesion between the insulating sheet and the binder. Various methods including known methods can be used for introducing or bonding the functional groups (preferably a hydroxyl group). Examples of suitable methods include corona discharge treatment, plasma treatment, UV irradiation treatment, and ITRO treatment.

In particular, plasma treatment is capable of introducing functional groups, and also removing smear generated by laser processing (desmear treatment), and thus preferred. Plasma treatment with the use of oxygen gas or oxygen/carbon tetrafluoride mixed gas is more preferred. Specifically, it is preferable to perform plasma treatment while allowing air or oxygen gas to flow inside through holes 12 of insulating sheet 21. This treatment makes inner wall surfaces 12c of through holes 12 hydrophilic, thereby further increasing the adhesiveness with base layer 22.

When, for example, a cross-linked product of a silicone-based elastomer composition constitutes insulating sheet 21, oxygen plasma treatment on insulating sheet 21 enables ashing and etching, and also oxidizing the surface of the silicone to form a silica film. The formation of the silica film more likely to allow the plating solution to enter through hole 12 and the adhesion between base layer 22 and the inner wall surface of through hole 12 to increase.

The oxygen plasma treatment can be performed by using, for example, a plasma asher, a radio frequency plasma etching apparatus, or a micro wave plasma etching apparatus.

Alternatively, treatment with the use a silane coupling agent may be performed for increasing the adhesiveness with base layer 22. The silane coupling agent to be used is as described above. A functional group such as an amino group derived from a silane coupling agent is thus introduced into, for example, inner wall surface 12c of through hole 12. During the formation of base layer 22, the introduced group can form an ionic bond with the bonding site of the binder (for example, a site having a carboxyl group), thereby further increasing the adhesiveness between base layer 22 and inner wall surface 12c of through hole 12 and the like.

Alternatively, as the elastomer or resin constituting insulating layer 11, a material having a hydroxyl group on the surface may be selected.

The resulting anisotropic conductive sheet can be preferably used for electrical testing.

### 3. Electrical Testing Apparatus and Electrical Testing Method

### Electrical Testing Apparatus

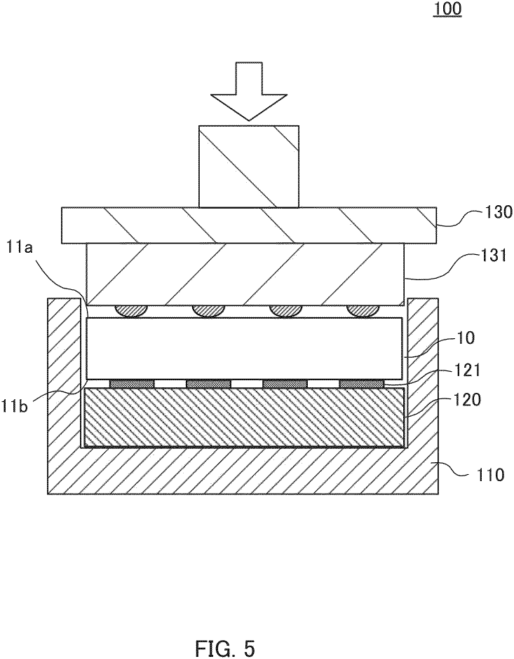

FIG. 5 is a sectional view illustrating an example of electrical testing apparatus 100 according to the present embodiment.

Electrical testing apparatus 100 uses anisotropic conductive sheet 10 of FIG. 1B and inspects the electrical characteristics (such as conduction) between terminals 131 (measurement points) of inspection object 130, for example. FIG. 5 also illustrates inspection object 130 for describing the electrical testing method. In addition, the cross-sectional view of anisotropic conductive sheet 10 is the same as that of FIG. 1B, and thus the illustration thereof is omitted.

As illustrated in FIG. 5, electrical testing apparatus 100 includes holding container (socket) 110, inspection substrate 120, and anisotropic conductive sheet 10.

Holding container (socket) 110 is a container for holding inspection substrate 120, anisotropic conductive sheet 10 and the like.

Inspection substrate 120 is disposed in holding container 110, and includes, at the surface facing inspection object 130, plurality of electrodes 121 facing corresponding measurement points of inspection object 130.

Anisotropic conductive sheet 10 is disposed on or above inspection substrate 120 at the surface where electrodes 121 are disposed, in such a way that electrodes 121 are in contact with conductive layers 13 of anisotropic conductive sheet 10 on second surface 11b side.

Inspection object 130 is not limited, but examples thereof include various semiconductor devices (semiconductor packages) such as HBM and PoP, electronic components, and printed boards. When inspection object 130 is a semiconductor package, the measurement point may be a bump (terminal). In addition, when inspection object 130 is a printed board, the measurement point may be a measurement land or a component mounting land provided on the conductive pattern.

### Electrical Testing Method

An electrical testing method using electrical testing apparatus 100 of FIG. 5 is described below.

As illustrated in FIG. 5, the electrical testing method according to the present embodiment includes a step of stacking inspection object 130 and inspection substrate 120 including electrodes 121 via anisotropic conductive sheet 10, and electrically connecting electrodes 121 of inspection substrate 120 with terminals 131 of inspection object 130 via anisotropic conductive sheet 10.

When the above-described step is performed, inspection object 130 may be pressurized for bringing terminals 131 into contact with anisotropic conductive sheet 10, or may be brought contact with anisotropic conductive sheet 10 in a heated atmosphere, from the viewpoint of facilitating sufficient conductivity between electrodes 121 of inspection substrate 120 and terminals 131 of inspection object 130 via anisotropic conductive sheet 10.

As described above, anisotropic conductive sheet 10 includes base layer 16 disposed between inner wall surface 12c of through hole 12 and metal plating layer 17. Base layer 16 allows metal plating layer 17 to satisfactorily adhere with inner wall surface 12c of through hole 12. This configuration can prevent the peeling of metal plating layer 17 even when anisotropic conductive sheet 10 is repeatedly and elastically deformed in the thickness direction by pressurization and depressurization during electrical testing. Therefore, satisfactory electrical connection between the substrate of an electrical testing apparatus and an inspection object becomes possible.

In addition, anisotropic conductive sheet 10 in the present embodiment includes conductive layer 13 not only on inner wall surface 12c of through hole 12, but also on first surface 11a and second surface 11b of insulating layer 11 (or the surfaces of anisotropic conductive sheet 10). In this manner, during electrical testing, electrical contact can be reliably performed when the anisotropic conductive sheet is placed between the electrode of the inspection substrate and the terminal of the inspection object and pressurized.

### Modification

The above embodiment describes anisotropic conductive sheet 10 illustrated in FIG. 1 as an example; however, the present invention is not limited thereto.

FIGS. 6A and 6B are partially enlarged views illustrating anisotropic conductive sheet 10 according to other embodiments. The above embodiment describes an example in which conductive layers 13 are disposed on both first surface 11a and second surface 11b of insulating layer 11 (see FIG. 1B). However, conductive layer 13 may be disposed only on first surface 11a of insulating layer 11 (see FIG. 6A).

In addition, the above embodiment describes an example in which the entire insulating layer 11 is an elastic body layer, but the insulating layer is not limited thereto, and may further includes one or more additional layers within the range such that the insulating layer can be elastically deformed. For example, insulating layer 11 may include elastic body layer 11A including first surface 11a (or a second surface 11b), and heat-resistant resin layer 11B including second surface 11b (or the first surface 11a) (see FIG. 6B).

### Heat-Resistant Resin Layer 11B

Heat-resistant resin layer 11B is composed of a heat-resistant resin composition.

The heat-resistant resin composition constituting heat-resistant resin layer 11B preferably has a glass transition temperature higher than that of the cross-linked elastomer composition constituting elastic body layer 11A. Specifically, since electrical testing is performed at approximately -40 to 150° C., the glass transition temperature of the heat-resistant resin composition is preferably 150° C. or above, more preferably 150 to 500° C. The glass transition temperature of the heat-resistant resin composition can be measured by a method similar to the above-mentioned method.

The heat-resistant resin composition constituting heat-resistant resin layer 11B preferably has a coefficient of thermal expansion lower than that of the cross-linked elastomer composition constituting elastic body layer 11A. Specifically, the coefficient of thermal expansion of the heat-resistant resin composition constituting heat-resistant resin layer 11B is preferably 60 ppm/K or smaller, more preferably 50 ppm/K or smaller.

In addition, heat-resistant resin layer 11B is immersed in a chemical solution, for example, in electroless plating treatment, and thus the heat-resistant resin composition constituting the heat-resistant resin layer preferably has chemical resistance.

The heat-resistant resin composition constituting heat-resistant resin layer 11B preferably has a storage elastic modulus higher than that of the cross-linked elastomer composition constituting elastic body layer 11A.

The composition of the heat-resistant resin composition is not limited as long as the glass transition temperature, the coefficient of thermal expansion, or the storage elastic modulus satisfies the above-described range, and the heat-resistant resin composition has a chemical resistance. Examples of the resin in the heat-resistant resin composition include engineering plastics, such as polyamide, polycarbonate, polyarylate, polysulfone, polyether sulfone, polyphenylene sulfide, polyetheretherketone, polyimide, and polyetherimide, acrylic resin, urethane resin, epoxy resin, and olefin resin. The heat-resistant resin composition may further include other components such as filler as necessary.

Thickness Tb of heat-resistant resin layer 11B is not limited, but is preferably less than thickness Ta of elastic body layer 11A from the viewpoint of less likely impairing of the elasticity of insulating layer 11 (see FIG. 6B). Specifically, the ratio of thickness Tb of heat-resistant resin layer 11B to thickness Ta of elastic body layer 11A, namely ratio (Tb/Ta), is, for example, preferably 5/95 to 30/70, more preferably 10/90 to 20/80. A ratio of the thickness of the heat-resistant resin layer 11B of a certain value or more can impart appropriate hardness (stiffness) to insulating layer 11 without impairing the elasticity (deformability) of insulating layer 11. This configuration can not only increase the handleability, but also reduce fracture of conductive layer 13 caused by expansion and contraction of insulating layer 11 and the like and reduce variation of the center-to-center distance of the plurality of through holes 12 caused by heat.

As described above, in anisotropic conductive sheet 10 of FIG. 6B, insulating layer 11 includes elastic body layer 11A having high elasticity, and heat-resistant resin layer 11B having high heat resisting properties (or low coefficient of thermal expansion). Therefore, appropriate hardness (stiffness) can be provided to insulating layer 11 without impairing the elasticity (deformability) of insulating layer 11. This configuration can not only increase the handleability, but also reduce fracture of conductive layer 13 due to expansion from heat and contraction of insulating layer 11 and the like and variation of the center-to-center distance of the plurality of through holes 12 due to heat.

Each of elastic body layer 11A and heat-resistant resin layer 11B may be composed of one layer or two or more layers. In addition, an adhesive layer (not illustrated) or the like may also be included.

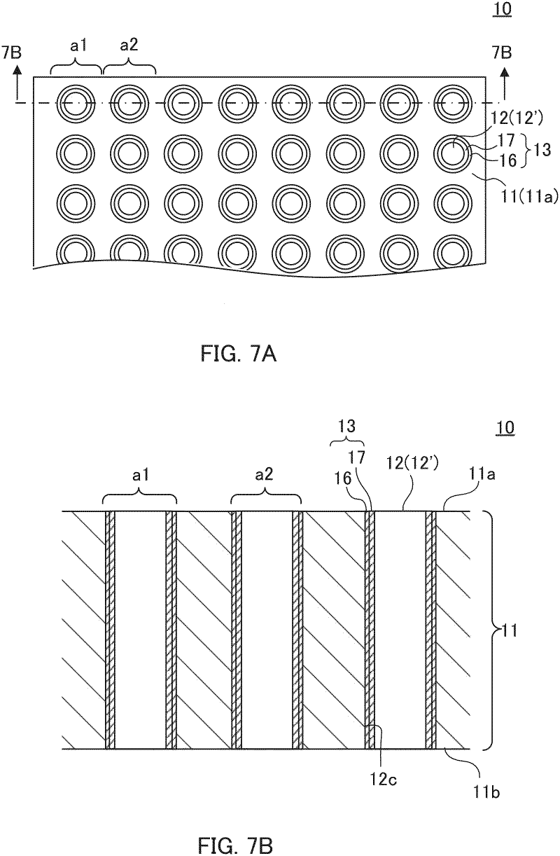

FIG. 7A is a plan view illustrating the anisotropic conductive sheet according to yet anoter embodiment, and FIG. 7B is a partially enlarged sectional view of the anisotropic conductive sheet of FIG. 7A taken along line 7B-7B.

The above embodiment describes an example in which conductive layer 13 is disposed not only on inner wall surface 12c of through hole 12 but also on first surface 11a and second surface 11b of insulating layer 11 (see FIG. 1B). However, conductive layer 13 may be disposed on only on inner wall surface 12c of through hole 12 (see FIG. 7B). In this case, the two adjacent through holes 12 are insulated from each other, and thus neither first groove part 14 nor second groove part 15 is required.

The anisotropic conductive sheet is used for electrical testing in the above embodiments; however, the present invention is not limited thereto. The anisotropic conductive sheet may be used for electrical connection between two electronic members, such as electrical connection between a glass substrate and a flexible printed board, and electrical connection between a substrate and an electronic component mounted thereon.

This application claims priority based on Japanese Patent Application No. 2020-015630, filed on Jan. 31, 2020, the entire contents of which including the specification and the drawings are incorporated herein by reference.

### Industrial Applicability

The present invention can provide an anisotropic conductive sheet capable of minimizing the peeling of a conductive layer associated with elastic deformation of the sheet in the thickness direction, and capable of performing satisfactory electrical connection between the substrate of the electrical testing apparatus and an inspection object; and an electrical testing apparatus and an electrical testing method each using the anisotropic conductive sheet.

### REFERENCE SIGNS LIST

10 Anisotropic conductive sheet
11 Insulating layer
11a First surface
11b Second surface
11A Elastic body layer
11B Heat-resistant resin layer
12 Through hole
12c Inner wall surface
13, 24 Conductive layer
14 First groove part
15 Second groove part
16, 22 Base layer
17, 23 Metal plating layer
21 Insulating sheet
100 Electrical testing apparatus
110 Holding container
120 Inspection substrate
121 Electrode
130 Inspection object
131 Terminal (of inspection object)

1. A anisotropic conductive sheet, comprising:
an insulating layer including a first surface located on one side in a thickness direction, a second surface located on another side in the thickness direction, and a plurality of through holes each extending between the first surface and the second surface; and
a plurality of conductive layers respectively disposed on inner wall surfaces of the plurality of through holes,
wherein each of the plurality of conductive layers includes:
a base layer that is disposed on each of the inner wall surfaces of the plurality of through holes, the base layer containing a metal-containing thin film and a binder with at least a part thereof disposed between each of the inner wall surfaces of the plurality of through holes and the metal-containing thin film, and
a metal plating layer disposed on or above the base layer so as to be in contact with the metal-containing thin film, and
wherein the binder is a sulfur-containing compound having a thiol group, a sulfide group, or a disulfide group.

2. The anisotropic conductive sheet according to claim 1, wherein:
the sulfur-containing compound further comprises a bonding site for bonding to each of the inner wall surfaces of the plurality of through holes.

3. The anisotropic conductive sheet according to claim 2, wherein:
the bonding site has a functional group selected from the group consisting of an alkoxysilyl group, a silanol group, an amino group, an imino group, a carboxyl group, a carbonyl group, a sulfonyl group, an alkoxy group, a hydroxyl group, and an isocyanate group.

4. The anisotropic conductive sheet according to claim 2, wherein:
the sulfur-containing compound has an aromatic heterocycle.

5. The anisotropic conductive sheet according to claim 4, wherein:
the sulfur-containing compound is a triazine thiol compound.

6. The anisotropic conductive sheet according to claim 1, wherein:
the metal-containing thin film contains a metal nanoparticle.

7. The anisotropic conductive sheet according to claim 6, wherein:
the metal nanoparticle has an average particle size of 1 to 30 nm.

8. The anisotropic conductive sheet according to claim 1, wherein:
metal in the metal-containing thin film contains gold, silver, or platinum.

9. The anisotropic conductive sheet according to claim 1, wherein:
the base layer has a thickness of 10 to 500 nm.

10. The anisotropic conductive sheet according to claim 1, wherein:
when a thickness of the base layer is T1 and a thickness of the metal plating layer is T2,
a thickness ratio T1 /(T1 +T2) is 0.0025 to 0.5.

11. The anisotropic conductive sheet according to claim 1, wherein:
each of the plurality of conductive layers is continuously disposed from each of the inner wall surfaces of the plurality of through holes to an area surrounding an opening of each of the plurality of through holes, the opening being located at the first surface; and
at the first surface, the anisotropic conductive sheet further includes a plurality of first groove parts disposed between the plurality of conductive layers for insulating the plurality of conductive layers from each other.

12. The anisotropic conductive sheet according to claim 1, wherein:
the insulating layer includes an elastic body layer.

13. The anisotropic conductive sheet according to claim 12, wherein:
the elastic body layer contains a cross-linked product of a silicone-based elastomer composition.

14. The anisotropic conductive sheet according to claim 3, wherein:
each of the inner wall surfaces of the plurality of through holes comprises a functional group; and
the functional group on each of the inner wall surfaces of the plurality of through holes and the functional group of the sulfur-containing compound are bonded to each other by a reaction.

15. The anisotropic conductive sheet according to claim 1, wherein:
a center-to-center distance of openings of the plurality of through holes on a side of the first surface is 5 to 100 µm.

16. The anisotropic conductive sheet according to claim 1, wherein:
the anisotropic conductive sheet is used for electrical testing of an inspection object; and
the inspection object is disposed on or above the first surface.

17. An electrical testing apparatus, comprising:
an inspection substrate including a plurality of electrodes; and
the anisotropic conductive sheet according to claim 1 disposed on or above a surface of the inspection substrate, wherein the plurality of electrodes are disposed on the surface.

18. An electrical testing method, comprising:
stacking, via the anisotropic conductive sheet according to claim 1, an inspection substrate including a plurality of electrodes, and an inspection object including a terminal, and electrically connecting the plurality of electrodes of the inspection substrate with the terminal of the inspection object via the anisotropic conductive sheet.
